(19) United States
(12) Patent Application Publication
(10) Pub. No.: US 2017/0354064 A1
(43) Pub. Date: Dec. 7, 2017

(54) MODULAR DATA CENTER FACILITY WITH COOLING MODULES

(71) Applicant: HDT Expeditionary Systems, Inc., Solon, OH (US)

(72) Inventors: Wade Milek, Florence, KY (US); Charles Deighton, Milford, OH (US)

(73) Assignee: HDT Expeditionary Systems, Inc., Solon, OH (US)

(21) Appl. No.: 15/173,391

(22) Filed: Jun. 3, 2016

(51) Int. Cl. H05K 7/20; H05K 7/14

(52) U.S. Cl. CPC H05K 7/20745; H05K 7/1488

(57) ABSTRACT

A modular housing encloses a data center and a modular cooling system. The modular cooling system includes a modular cooling pallet on which cooling modules are installed. Each cooling module can have different cooling properties and may cool air to a different temperature than that of air cooled by other cooling modules. This can fulfill the different cooling needs among different computers that reside in the data center. The modular housing may also provide features that enable it to be quickly assembled at an operating site. The modular housing may comprise wall structures, roof structures, and a floor structure that are embedded with fastening features, which eliminates use of loose fasteners used for assembly. The floor structure may be made of rack pallets that provide wire ways through which connections can be routed, which simplifies the wiring process when assembling the modular housing on site.

### CROSS-REFERENCES TO RELATED APPLICATIONS

None.

### BACKGROUND

Containerized solutions have often been utilized for building data centers. Such containerized solutions utilize ISO (International Standards Organization) standard shipping containers, which are modified and populated with data center electronic equipment. However, numerous issues can arise when utilizing these containers for data centers.

Since shipping containers are not originally built for the purpose of being utilized for data centers, they are limiting and not sufficient for the needs of a data center. For example, the containers are limiting in size, which can prevent certain functionality from being able to be retrofitted to the containers. Further, the containers may not be able to support hardware from a variety of manufacturers, further complicating the retrofitting process. Thus, such containers may not be able to effectively accommodate for specific uses of various data center providers.

Additionally, the building process for the containerized solution is not optimal. The containers comprising data center equipment are built and tested prior to being shipped to the data center operating site. While this approach forgoes assembly at the operating site, there is a higher risk of poor quality control due to shipment and handling of the containers and the use of the containers at a different site from the environment in which they were tested. Further, the same building processes are not repeated for containers being retrofitted for the different needs of each data center. This inconsistent building process may further exacerbate the risk of poor quality control.

Containerized solutions also are not able to fulfill the cooling needs for computers in data centers. Data centers can host a plurality of computers, where the computers typically run different processes and loads. This results in different amounts of heat generated by the computers, which makes a uniform cooling process for the computers ineffective. However, containerized solutions do not provide the ease of configuration for enabling systems that can cool computers according to their individual cooling needs.

While the above-described architectures can be used, a number of improvements could be made.

Thus, new and enhanced methods for building data centers are needed. Embodiments of the invention address these and other problems, individually and collectively.

### BRIEF SUMMARY

Embodiments of the invention are directed to systems and methods related to a modular housing adapted to house a data center, including the process of assembling the modular housing. The modular housing may comprise a plurality of panels, at least one modular cooling pallet, a plurality of wall structures, and at least one cooling module on the at least one cooling pallet. The plurality of panels and the plurality of wall structures can form an enclosure housing the data center, the at least one modular cooling pallet, and the at least one cooling module. The at least one modular cooling pallet may comprise a modular cooling pallet frame to which one or more of the at least one cooling module can be attached. In some embodiments, the at least one modular cooling pallet may comprise an unpopulated area on which no cooling module is attached.

In some embodiments, the at least one modular cooling pallet with the at least one cooling module is at the top of the enclosure and may form a peak. The modular housing may be configured to enclose a first row of computers and second row of computers. The at least one cooling module may direct cooled air downwards between the first and second row of computers.

The modular housing may also comprise a plurality of fluid supply lines and a plurality of fluid return lines. The fluid supply lines may be configured to pass cooling fluid into each of the at least one cooling module. The fluid return lines may be configured to remove cooling fluid from each of the at least one cooling module.

In some embodiments, each of the at least one cooling module may comprise a fan, a heat exchanger coil, and a duct. The heat exchanger coil may receive the cooling fluid from a fluid supply line. The cooling fluid in the heat exchanger coil can remove heat from the air drawn into the duct by the fan. The heat exchanger coil may then remove the heated cooling fluid from the cooling module through a fluid return line.

In some embodiments, the at least one cooling module may comprise a first cooling module and a second cooling module. In some embodiments, the first and second cooling modules may each configured to provide different cooling properties. For example, the first cooling module may cool air to a cooler temperature than that of the air cooled by the second cooling module. In some embodiments, the first and second cooling modules may each be configured to be different sizes.

The modular housing may also comprise a rack pallet and a plurality of wires. The rack pallet may be at the bottom of the modular housing and support the plurality of wall structures. The rack pallet may also be configured to receive a plurality of wires. The plurality of wires may be electrically coupled to the first and second rows of computers.

Embodiments of the invention are also directed to a system comprise a modular housing adapted to house a data center, a first row of computers, and a second row of computers. The modular housing may comprise a plurality of panels, at least one modular cooling pallet, a plurality of wall structures, and at least one cooling module on the at least one modular cooling pallet. The plurality of panels and the plurality of wall structures may form an enclosure housing the data center, the at least one modular cooling pallet, and the at least one cooling module.

The modular housing may be configured to enclose the first row of computers and the second row of computers. In some embodiments, the at least one modular cooling pallet with the at least one cooling module is at the top of the enclosure. The at least one cooling module may directs cold air downwards between the first and second rows of computers. In some embodiments, the cold air may pass through the first row of computers to form a first hot air stream that passes between the first row of computers and an adjacent first wall structure. Additionally, the cold air may pass through the second row of computers to form a second hot air stream that passes between the second row of computers and an adjacent second wall structure. The at least one cooling module can draw hot air from the first hot air stream or the second hot air stream, cool the hot air, and redirect the cooled air downward between the first and second rows of computers.

In some embodiments, the at least one cooling module may comprise a first cooling module and a second cooling module. In some embodiments, the first and second cooling modules may each configured to provide different cooling properties. For example, the first cooling module may cool air to a cooler temperature than that of the air cooled by the second cooling module. In some embodiments, the first and second cooling modules may each be configured to be different sizes.

The system may also comprise a rack pallet and a plurality of wires. The rack pallet may be at the bottom of the modular housing and support the plurality of wall structures. The rack pallet may also be configured to receive a plurality of wires. The plurality of wires may be electrically coupled to the first and second rows of computers.

Embodiments of the invention are further directed to a method of using the system. The method may comprise receiving hot air from the first hot air stream or the second hot air stream, cooling the hot air using the at least one cooling module, and directing the cooled air downwards between the first and second rows of computers. Each of the at least one cooling module may cool the hot air to a certain temperature.

Embodiments of the invention are further directed to a modular housing. The modular housing may comprise a first wall structure embedded with cam-lock assembly parts and a second wall structure embedded with cam-lock assembly parts. The cam-lock assembly parts embedded in the first wall structure may be fastened to the cam-lock assembly parts embedded in the second wall structure to connect the first wall structure and the second wall structure. In some embodiments, the cam-lock assembly parts embedded in the first wall structure include cams and receptacles and the cam-lock assembly parts embedded in the second wall structure include receptacles and cams, wherein the cams embedded in the first wall structure fasten to the receptacles embedded in the second wall structure and the receptacles embedded in the first wall structure fasten to the cams embedded in the second wall structure.

In some embodiments, each of the first wall structure and the second wall structure may comprise a cam-lock groove meant to hold a cam-lock assembly part, a panel pocket meant to hold a panel, a gasket pocket meant to hold a gasket, and gasket seal contact surface. In some cases, the first wall structure may be further embedded with a gasket pocket comprising a gasket, where the gasket can compress against the second wall structure to create a seal when the first wall structure and the second wall structure are fastened together.

The modular housing may further comprise a roof structure embedded with cam-lock assembly parts and a floor structure embedded with cam-lock assembly parts. The cam-lock assembly parts embedded in the first wall structure and the second wall structure may be fastened to the cam-lock assembly parts embedded in the roof structure to connect the first wall structure and the second wall structure to the roof structure. Further, the cam-lock assembly parts embedded in the first wall structure and the second wall structure may be fastened to the cam-lock assembly parts embedded in the floor structure to connect the first wall structure and the second wall structure to the floor structure.

These and other embodiments of the invention are described in further detail below.

### BRIEF DESCRIPTION OF DRAWINGS

FIG. 1 shows a side view of a modular housing comprising a modular cooling system according to embodiments of the invention.

FIG. 2 shows an exemplary modular cooling pallet according to embodiments of the invention.

FIG. 3 shows an exemplary modular cooling pallet with an unpopulated area according to embodiments of the invention.

FIG. 4 shows some components that make up a cooling module according to embodiments of the invention.

FIG. 5 shows a modular cooling pallet frame of a modular cooling pallet according to embodiments of the invention.

FIG. 6A-6F shows the assembly of a modular housing according to embodiments of the invention.

FIG. 7 shows a close up of a wall structure according to embodiments of the invention.

FIG. 8 shows adjacent wall structures fastened together according to embodiments of the invention.

FIG. 9 shows an extrusion profile of an extrusion of a wall structure according to embodiments of the invention.

FIG. 10 shows an extrusion profile of an extrusion connected to a wall structure according to embodiments of the invention.

FIG. 11 shows a top section view of a corner formed by attaching adjacent wall structures according to embodiments of the invention.

FIG. 12 shows a rack pallet according to embodiments of the invention.

FIG. 13 shows a close up of wire ways of a rack pallet according to embodiments of the invention.

FIG. 14 shows cam-lock assembly parts according to embodiments of the invention.

FIG. 15 shows fastened cam-lock assembly parts according to embodiments of the invention.

FIG. 16 shows cross section of fastened cam-lock assembly parts according to embodiments of the invention.

### DETAILED DESCRIPTION

Embodiments of the invention are directed to a modular cooling system utilized in a modular data center facility. The modular cooling system may include a modular cooling pallet, which can be installed with one or more cooling modules. Each cooling module may produce a specific air condition cooling capacity, which can allow computers housed in particular locations within the modular housing to be maintained at desired temperatures. In some embodiments, the cooling pallet may be at the top of the enclosure housing the data center and may direct cold air downwards between a first and second row of computers.

Recent changes in the data center industry have brought about trends, such as the utilization of cooperative style data centers. Such cooperative style data centers provide the ability for users (e.g., companies) to rent one or more racks from a data center provider. Hence, these cooperative style data centers can often house racks comprising computers associated with a plurality of different users. The racks may be 19-inch racks, which are standardized frames that can be mounted with electronic equipment. The electronic equipment mounted on each 19-inch rack may produce heat when used, typically in the range of 5 kilowatts to 35 kilowatts per 19-inch rack, which results in the need for cooling the ambient air that surrounds the 19-inch racks to avoid damage to the electronic equipment.

However, in some cases, one section of the data center may house racks comprising computers associated with a first user and another section of the data center may house racks comprising computers for a second user. The resulting power consumption and heat generated by the computers associated with the first user may vary from that of the computers associated with the second user. As a result, the cooling needs of certain computers may vary based on operation by different users. Thus, a uniform cooling process is not effective for serving the air conditioning needs for computers in the data center.

Embodiments of the invention solve this issue by enabling cooling modules that can each provide modular cooling processes for computers within the data center. The utilization of such modular cooling processes can enable computers to be cooled according to their own air conditioning needs. For example, a first group of computers may be generating more heat than a second group of computers within the data center. The first group of computers that is generating more heat may then be subjected to more powerful air conditioning than the second group of computers. This can allow the first group of computers to be cooled to an appropriate temperature independent of the different cooling needs of the second group of computers. Hence, the modular cooling system enables a way to provide more effective and customized cooling processes for computers in the data center.

Embodiments of the invention are also directed to a modular housing utilized for the modular data center facility. The modular housing may be adapted to house a data center and the modular cooling system described above. Instead of a containerized solution utilizing shipping containers (e.g., ISO containers) that are pre-built, the modular housing can be assembled at the operating site utilizing modular building blocks. For example, a housing may comprise a plurality of panels and a plurality of connectable walls that may be assembled to form an enclosure housing the data center. There may also be a floor structure comprising rack pallets on which racks and computers may be placed within the housing. The rack pallets enable wiring of computers on the racks to be pre-assembled, which further simplifies the assembly of the modular housing comprising the data center. In some embodiments, components of the modular housing may be connected utilizing wall connecting technology involving cam-lock assembly parts and gaskets, described in further detail below.

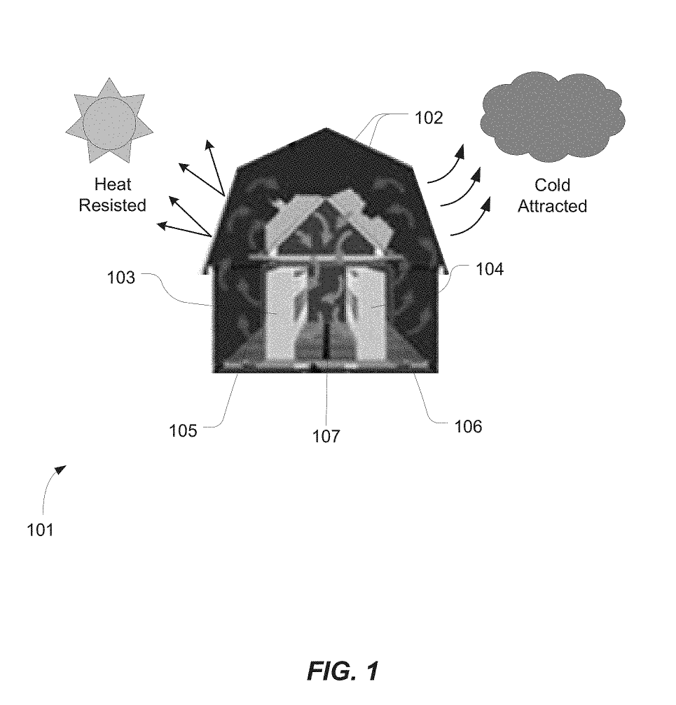

FIG. 1 shows a side view of a modular housing 101 comprising a modular cooling system according to embodiments of the invention. The modular housing 101 may form an enclosure housing a data center, which may include a first row of computers 103 and a second row of computers 104. The modular housing 101 may further comprise a modular cooling pallet 102, a first hot aisle 105, a second hot aisle 106, and a cold aisle 107. It is understood that FIG. 1 shows modular housing 101 having no side wall for purposes of demonstration, and that the modular housing 101 is typically enclosed by wall structures on all sides.

Modular cooling pallet 102 may enable cooling within the modular housing 101. In some embodiments, modular cooling pallet 102 may be located above the first row of computers 103 and the second row of computers 104 and may form a peak. The first row of computers 103 and the second row of computers 104 may be in use and may generate heat inside of the modular housing 101. Modular cooling pallet 102 may draw hot air generated due to the heat from the computers, cool the hot air using its cooling modules, and direct the cooled air downwards between the first row of computers 103 and the second row of computers 104.

The cooling air flow circuit provided by modular cooling pallet 102 may enable generation of the first hot aisle 105, the second hot aisle 106, and the cold aisle 107. The first hot aisle 105 may reside between the first row of computers 103 and the wall structure shown on the left side of modular housing 101 and the second hot aisle 106 may reside between the second row of computers 104 and the wall structure shown on the right side of modular housing 101. The cold aisle 107 may reside between the first row of computers 103 and the second row of computers 104.

In some cases, it is recommended that the temperature of cold aisle 107 of the data center is to be kept somewhere in the range of 68 degrees Fahrenheit and 77 degrees Fahrenheit (i.e., 20 degrees Celsius to 25 degrees Celsius). While cold aisle 107 may be able to maintain temperatures outside of this range, it is noted that keeping cold aisle 107 at too low of a temperature can be costly and a waste of energy. On the other hand, even though keeping cold aisle 107 at a higher temperature may be energy efficient, there is a higher risk of damage to the equipment in the data center in the event of a cooling system failure.

The first hot aisle 105 and the second hot aisle 106 may have hot air due to heat generated by the first row of computers 103 and the second row of computers 104, respectively. In some cases, cold air from cold aisle 107 may pass through the first row of computer 103 to generate a first hot air stream that passes into the first hot aisle 105. Cold air from cold aisle 107 may also pass through the second row of computers 104 to generate a second hot air stream that passes into the second hot aisle 106.

In some embodiments, the modular cooling pallet 102 may control air flow to prevent air from moving in undesired direction. Modular cooling pallet 102 may ensure that hot air is drawn from the first hot aisle 105 and the second hot aisle 106 by its cooling modules, which can then cool the hot air. The cooling modules of modular cooling pallet 102 may then direct the cooled air downward in between the first row of computers 103 and the second row of computers 104 into the cold aisle 107. The cooling modules may cool air released into cold aisle 107 to a certain designated temperature that enables the first row of computers 103 and the second row of computers 104 to run under optimal conditions. The cold aisle 107 may also enable workers to safely access the first row of computers 103 and the second row of computers 104 for maintenance or other reasons.

The placement of each hot aisle between a row of computers and an outer wall structure of modular housing 101 provides advantages. One such advantage is that the placement reduces cooling loads on the modular cooling system based on thermodynamic optimization and heat transfer properties. For example, the arrangement of hot aisles 105 and 106 and cold aisle 107 within modular housing 101 ensures that the hot air within modular housing 101 is against the outer walls of modular housing 101. This reduces the heat transfer from a hot external environment into the interior of modular housing 101. Reducing the heat transferred into modular housing 101 reduces the load on the modular cooling system. Additionally, in cases in which the external environment is cold, heat may be transferred from the interior of modular housing 101 to the exterior of modular housing 101 through heat conduction. This again reduces the load on the modular cooling system.

Reducing the load on the modular cooling system is energy efficient. For example, as shown in FIG. 1, cooler temperatures outside the modular housing 101 may attract heat from second hot aisle 106. Accordingly, heat may be dissipated from the second hot aisle 106 to the outside of modular housing 101, which may reduce the temperature of second hot aisle 106. As a result, modular cooling pallet 102 does not have to utilize as much energy to cool the air drawn from second hot aisle 106 to a designated temperature. In another example, as shown in FIG. 1, first hot aisle 105 may resist heat from the hot weather outside of the modular housing 101. This may reduce additional heat from being transferred from the outside of the modular housing 101 into first hot aisle 105. This forgoes the need for the modular cooling pallet 102 to utilize more energy to cool the air drawn from first hot aisle 105. Thus, the placement of each hot aisle against an outer wall structure of modular housing 101 reduces the load on the modular cooling system and saves energy.

It is understood that the temperature outside of the first hot aisle 105 and the second hot aisle 106 of modular housing 101 will typically be similar. Thus, while only second hot aisle 106 is described above as dissipating heat to the outside of the modular housing 101 for purposes of demonstration, it is understood that the first hot aisle 105 may also dissipate heat as described under similar conditions with cold external environments. Additionally, while only first hot aisle 105 is described above as resisting heat from the outside of the modular housing 101 for simplicity, it is understood that second hot aisle 106 may also resist heat as described under similar conditions with hot external environments.

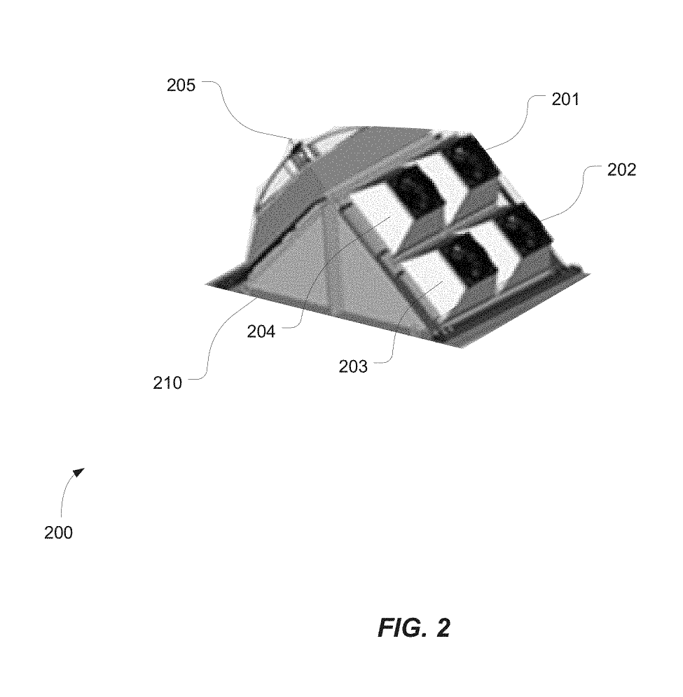

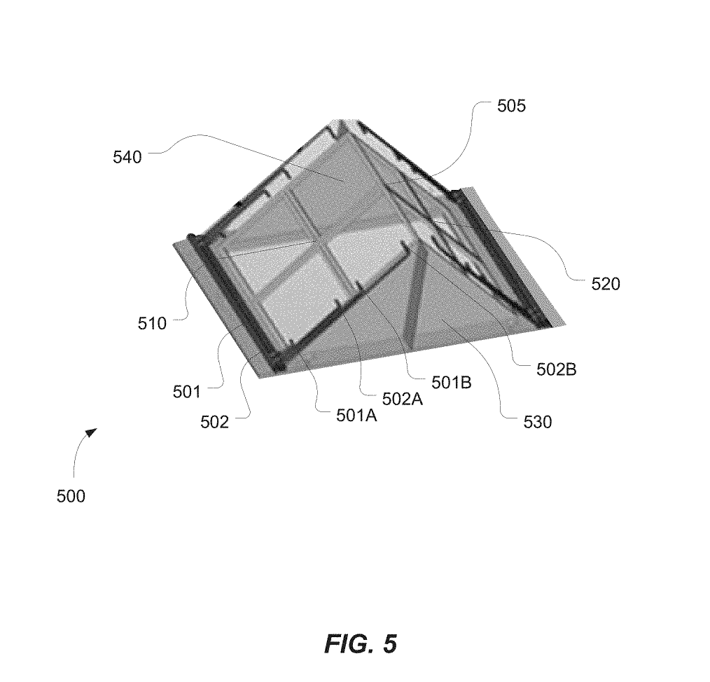

FIG. 2 shows an exemplary modular cooling pallet 200 according to embodiments of the invention. Modular cooling pallet 200 may comprise cooling modules 201 to 205, which may be attached onto the slanted sides of a modular cooling pallet frame 210 that forms a peak shape. An exemplary modular cooling pallet frame is described in further detail with respect to FIG. 5.

A cooling module may be any suitable size that is compatible with modular cooling pallet 200. In some cases, four cooling modules of the same size may be installed as an array on one side of the modular cooling pallet 200. Examples of such cooling modules are shown by cooling modules 201, 202, 203, and 204, which may each provide different cooling properties. For example, each of the cooling modules 201, 202, 203, and 204 may be configured to cool air to a designated temperature, where the designated temperature may differ for each of the cooling modules. In other cases, a single larger cooling module may be installed on one side of modular cooling pallet 200. An example of a larger cooling module is shown by cooling module 205. Cooling module 205 may provide different cooling properties from that of cooling modules 201, 202, 203, and 204. For example, cooling module 205 may be configured to cool air to a different temperature that that of the air cooled by cooling modules 201, 202, 203, and 204. However, embodiments are not so limited, since it may also be possible that one or more of cooling modules 201 to 205 are configured to cool air to the same or a similar temperature.

While modular cooling pallet 200 is shown to have one large cooling module 205 on one side and four smaller cooling modules 201 through 204 on another side, embodiments are not so limited. In another exemplary configuration, modular cooling pallet 200 may have two large cooling modules each the size of cooling module 205, with one on each side of modular cooling pallet 200. In yet another exemplary configuration, modular cooling pallet 200 may have eight cooling modules, each the size of cooling module 210, four on each side of modular cooling pallet 200.

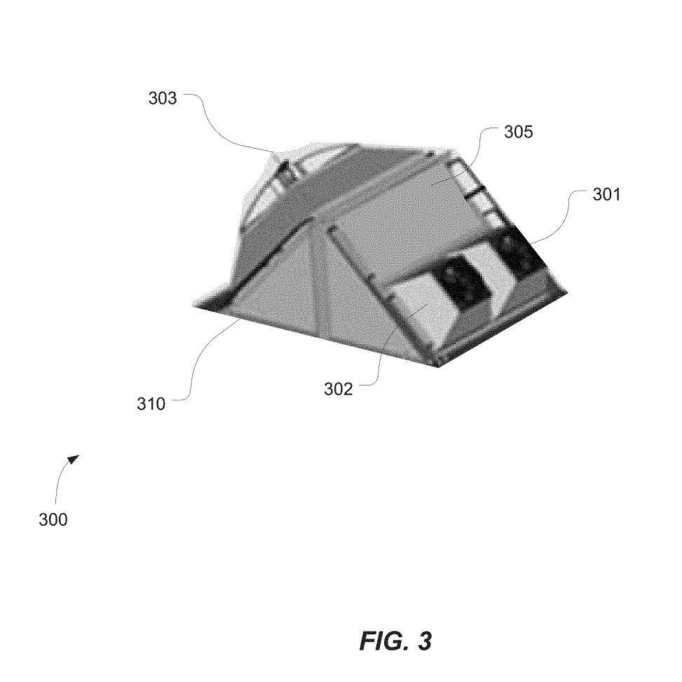

Further, in some embodiments, each side of a modular cooling pallet may not be fully installed with cooling modules. Hence, certain areas of the modular cooling pallet may not be populated with cooling modules. An example of such a modular cooling pallet is described with respect to FIG. 3.

FIG. 3 shows an exemplary modular cooling pallet 300 with an unpopulated area 305 according to embodiments of the invention. Modular cooling pallet 300 may comprise cooling modules 301, 302, and 303, which can each provide different cooling properties. However, unlike modular cooling pallet 200 shown in FIG. 2, modular cooling pallet 300 may further comprise unpopulated area 305. The cooling modules 301 to 303 and unpopulated area 305 may be attached onto the slanted sides of a modular cooling pallet frame 310 that forms a peak shape. An exemplary modular cooling pallet frame is described in further detail with respect to FIG. 5.

The unpopulated area 305 may be an area of modular cooling pallet 300 that does not comprise cooling modules. In some cases, unpopulated area 305 may be an section of modular cooling pallet frame 310 on which cooling modules could be attached, but is left unoccupied due to user preference. Unpopulated area 305 may comprise a cover structure, such as a panel, that covers the openings on modular cooling pallet frame 310 meant for attaching cooling modules. The cover structure may prevent air from flowing in or out of unpopulated area 305, so that air from within modular cooling pallet 300 does not directly mix with air outside of modular cooling pallet 300 without passing through a cooling module. The cover structure may be made out of any material suitable to withstand heat and block air, such as aluminum or steel.

Unpopulated area 305 may not have cooling modules installed for several reasons. For example, the user of modular cooling pallet 300 (e.g., entity utilizing computers being cooled by modular pallet 300) may determine that the cooling functionality providing by cooling modules 301, 302, and 303 is sufficient for their cooling needs. Thus, the user may choose not to install additional cooling modules in unpopulated area 305 in order to save time and costs related to installation and maintenance. The modular aspect of the modular cooling pallet 300 may provide flexibility regarding the number of cooling modules to be utilized, which can forego the need to install and maintain unnecessary cooling modules.

Additionally, the modular aspect of the modular cooling pallet 300 may enable a simple way to change modular cooling pallet 300 to accommodate a change in cooling needs. In some cases, the user of modular cooling pallet 300 may want modular cooling pallet 300 to provide more cooling than that currently being provided by modular cooling pallet 300. To accommodate, the user may adjust the cooling settings for one or more of cooling modules 301, 302, and 303. For example, the user may adjust the settings related to one or more of cooling module 301, 302, and 303 to cool air to a lower temperature that their originally designated temperatures. In other cases, the user of modular cooling pallet 300 may want modular cooling pallet 300 to provide less cooling than that currently being provided by modular cooling pallet 300. To accommodate, the user may adjust the cooling settings for one or more of cooling modules 301, 302, and 303. For example, the user may adjust cooling settings for one or more of cooling module 301, 302, and 303 to cool to a higher temperature than their originally designated temperatures. In some cases, the user may make any suitable combination of adjustments to the cooling settings of each of cooling modules 301, 302, and 303 so that the overall cooling provided by modular cooling pallet 300 fulfills their cooling needs.

Modular cooling pallet 300 may also enable an efficient way to accommodate for cases in which the existing cooling modules 301, 302, and 303 are not sufficient to fulfill the user's cooling needs. For example, cooling modules may be easily added to modular cooling pallet 300. To accommodate the user's cooling needs, one or two additional cooling modules may be installed in unpopulated area 305. This installation process is convenient as there is no need for replacement of already existing cooling modules, thus saving installation time and costs.

Modular cooling pallet 300 may also enable an efficient way to accommodate for cases in which one or more of the existing cooling modules 301, 302, and 303 may not be needed to fulfill the user's cooling needs. The cooling functionality of individual cooling modules may easily be turned off. For example, to accommodate the user's cooling needs while saving energy, the user may turn off the cooling functionality of one or more of cooling modules 301, 302, or 303. This is convenient, since no uninstallation or replacement process for the cooling modules is needed. This also leaves open the option for the user to turn on the functionality of the one or more cooling modules 301 through 303 for use again.

Modular cooling pallet 300 may further enable flexible uninstallation and replacement of cooling modules. There may be various reasons why a user may want to uninstall cooling modules. In some cases, the cooling modules may be broken and may need to be fixed or replaced. Uninstallation of these cooling modules is convenient because cooling modules may be individually uninstalled or replaced without affecting other cooling modules and hardware of modular cooling pallet 300. Further, modular cooling pallet 300 provides the option to allow cooling modules to be uninstalled without replacing them, since modular cooling pallet 300 can still function with unpopulated areas.

In other cases, the user of modular cooling pallet 300 may want to utilize cooling modules of different sizes from those already installed on modular cooling pallet 300. Instead of having to replace modular cooling pallet 300 with a different modular cooling pallet that comprises cooling modules with the different sizes that the user prefers, only certain individual cooling modules have to be replaced to accommodate the user's needs. The ability for individual cooling modules to be interchanged even after they have once been assembled as part of modular cooling pallet 300 provides convenience and flexibility.

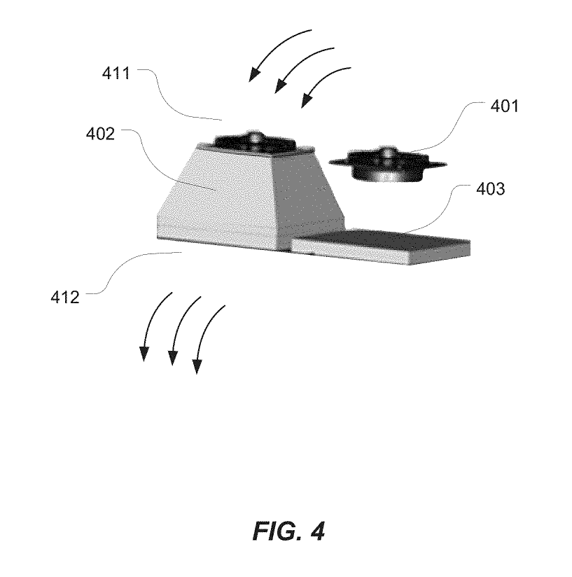

While FIG. 3 shows modular cooling pallet 300 comprising cooling modules 301 through 303, embodiments are not so limited. For example, modular cooling pallet 300 may have an array of different cooling modules installed from a quantity of one to eight cooling modules. The cooling modules may comprise any suitable combination of cooling modules of various sizes that are compatible with modular cooling pallet 300. In some embodiments, there may be one or more unpopulated areas on modular cooling pallet 300. Certain components of a modular cooling pallet are described with respect to FIG. 4 and FIG. 5.

FIG. 4 shows some components that make up a cooling module according to embodiments of the invention. FIG. 4 includes a fan 401, air flow duct 402, a heat exchanger coil 403, and inlet side 411, and an outlet side 412. It is understood that each cooling module may comprise a fan, an air flow duct, a heat exchanger coil, an inlet side, and an outlet side. The fan and heat exchanger coil attached to air flow duct 402 are duplicated as fan 401 and heat exchanger coil 403 in FIG. 4 for purposes of illustration. Thus, the following description refers to fan 401 and heat exchanger coil 403 as being part of the cooling module comprising air flow duct 402 shown in FIG. 4.

Fan 401 may be any suitable machine that can create air flow. Fan 401 may be attached on top of air flow duct 402. Fan 401 may draw air into inlet side 411 and direct the air into air flow duct 402 and out through outlet side 412. In some cases, fan 401 may be powered by an electric motor. The speed of the motor of fan 401 may be controlled to regulate the desired cooling output from the associated cooling module. In some embodiments, fan 401 may be an axial fan, a centrifugal fan, or other suitable type of fan.

Air flow duct 402 may be any suitable channel for delivering air. One end of air flow duct 402 may be attached underneath fan 401 and the other end of air flow duct 402 may be attached on top of heat exchanger coil 403. Air flow duct 402 may be any suitable shape so that it provides a hollow channel that can receive air drawn in by fan 401 and deliver the air to heat exchanger coil 403. While FIG. 4 shows air flow duct 402 as being a right frustum shape, embodiments are not so limited. Air flow duct 402 may be any suitable shape that can effectively receive and deliver air. For example, in other implementations, air flow duct 402 may be a cylinder, a rectangular prism, conical frustum, or other suitable shape. Air flow duct 402 may be made out of any suitable material that can withstand heat and does not allow air to pass through the material. For example, air flow duct may be made of conductive materials, such as aluminum and steel.

Heat exchanger coil 403 may be any suitable tubular coil that can circulate a fluid and enable heat transfer to the fluid within heat exchanger coil 403. Heat exchanger coil 403 may use any suitable coil type, such as a grid-type coil, a U-shape coil, a helical coil, a serpentine coil, or a combination of multiple coil types. It is understood that heat exchanger coil 403 may be configured to maximize its surface area to enable efficient heat transfer from air surrounding heat exchanger coil 403 to the fluid that is carried within heat exchanger coil 403, while minimizing the resistance of the fluid flowing through heat exchanger coil 403. Heat exchanger coil may be made of a material that has high conductivity, such as copper or aluminum. Typically, heat exchanger coil 403 may be made of copper for cost efficiency.

In some embodiments, heat exchanger coil 403 may receive a cooling fluid at one end and subsequently circulate the cooling fluid through its coil and out its other end. During this time, the cooling fluid in heat exchanger coil 403 may remove heat from the air surrounding heat exchanger coil 403 drawn into air flow duct 402 by fan 401. This may increase the temperature of the cooling fluid in heat exchanger coil 403. Heat exchanger coil 403 may then remove the hot cooling fluid from the cooling module. In some cases, the cooling fluid may be received from a fluid supply line coupled to the heat exchanger coil 403 and the cooling fluid may be removed through a fluid return line coupled to heat exchanger coil 403. The fluid supply line and the fluid return line are described in more detail with respect to FIG. 5. In some cases, the cooling fluid may be chilled water or other refrigerant.

Components of the cooling module may be controlled locally or remotely. In some cases, there may be a local controller that can be used to send instructions to the cooling module. For example, the local controller may be used to change the temperature to which the cooling module is to cool the incoming air, adjust the motor speed of fan 401, or change the throughput of cooling fluid that flows in heat exchanger coil 403. In some cases, the cooling module may be associated with a remote controller, which may be used in addition to or instead of the local controller. The local controller may be linked to the remote controller over a communications network over which the local controller and remote controller may send and receive instructions and information related to the cooling module. In some embodiments, the remote controller may be associated with a computer (e.g., in a control center) that can be used to manage settings corresponding to multiple cooling modules.

In some embodiments, the temperature of the cooling module may be tracked by a thermostat. The thermostat may be able to send recorded temperature data to the local controller or remote controller associated with the cooling module. In some cases, the cooling module may comprise an internal thermostat that can directly record the temperature of the cooling module. In some cases, the cooling module may be configured to communicate with a remote thermostat.

Components of the cooling module may be controlled based on the temperature tracked of the air within the cooling module. For example, the motor speed of fan 401 may be adjusted based on the tracked temperature in order to control the amount of hot air being received by air flow duct 402 and the amount of cooled air being delivered out of air flow duct 402. Additionally, the speed at which cooling fluid is circulated through the heat exchanger coil 403 may also be adjusted based on the tracked temperature in order to control the amount of time that the cooling fluid circulates within the heat exchanger coil 403. This amount of time may affect the amount of heat transferred from the air in air flow duct 403 to the cooling fluid within heat exchanger coil 403 before the cooling fluid is removed from the cooling module. The thermostat described above may continue to monitor the temperature inside the cooling module to determine whether these adjustments are sufficient to enable the cooling module to cool received air to a designated temperature. The thermostat may communicate the tracked temperatures to the local or remote controller, which may cause further adjustments to be made as necessary.

FIG. 5 shows a modular cooling pallet frame 500 of a modular cooling pallet according to embodiments of the invention. A modular cooling pallet may comprise modular cooling pallet frame 500 and one or more cooling modules. FIG. 5 also includes a fluid supply line 501 and a fluid return line 502.

Modular cooling pallet frame 500 may comprise a slanted surface 510 and a slanted surface 520, which may be joined at an angle to form peak 505. Modular cooling pallet frame 500 may also comprise surfaces 530 and 540 that cover the sides of modular cooling pallet frame 500. In some embodiments, slanted surfaces 510 and 520 and surfaces 530 and 540 may form a hollow triangular prism without a base surface. While FIG. 5 shows one example of modular cooling pallet frame 500, in other embodiments, modular cooling pallet frame 500 may form other suitable structures that comprise a peak. Modular cooling pallet frame 500 may be made out of any suitable conductive material, such as aluminum or steel that may be able to withstand heat.

One or more cooling modules can be installed on slanted surfaces 510 and 520. As described above with respect to FIG. 2 and FIG. 3, any suitable combination of one or more cooling modules of various sizes may be attached onto slanted surfaces 510 and 520. In some embodiments, slanted surfaces 510 and 520 may be sectioned into areas corresponding to the sizes of a cooling module. In some cases, each area may comprise an opening outlined by an edge that can be aligned to the base of a cooling module. In some cases, the edges may have attachment mechanisms that enable cooling modules to be attached to modular cooling pallet frame 500. Any suitable number of these attachment mechanisms may be occupied at a time. For example, some of the attachment mechanisms may be occupied when used to attach a cooling module to modular cooling pallet frame 500, while other attachment mechanisms in an unpopulated area (e.g., unpopulated area 305 of FIG. 3) may not be occupied. This can allow individual cooling modules to be attached and detached from modular cooling pallet frame 500 independently from other cooling modules. Any suitable attachment mechanisms may be utilized, such as snap-fits or screw fasteners.

Fluid supply line 501 and fluid return line 502 may be attached to modular cooling pallet frame 500. Fluid supply line 501 may be a conduit that can supply cooling fluid to one or more cooling modules attached to modular cooling pallet frame 500. Fluid supply line 501 may supply the cooling fluid to each of the heat exchanger coils of the cooling modules. Fluid return line 502 may be a conduit that can remove cooling fluid from the one or more cooling modules attached to modular cooling pallet frame 500. Fluid return line 502 may receive cooling fluid that has been circulated by each of the heat exchanger coils from the heat exchanger coils of the cooling modules. Fluid supply line 501 and fluid return line 502 may be made of any suitable material that can carry cooling fluid. In some embodiments, fluid supply line 501 and fluid return line 502 may be made of the same material as that of the heat exchanger coil in the cooling modules, such as copper or aluminum.

While not shown in FIG. 5, fluid supply line 501 and fluid return line 502 may be connected to a source that provides cooling fluid. In some cases, the source may be a cooling system (e.g., chiller, cooling tower, etc.) that cools and stores cooling fluid. Fluid supply line 501 may draw the cooled cooling fluid from the cooling system to modular cooling pallet frame 500 and into the cooling module. Fluid return line 502 may carry the cooling fluid removed from the cooling module of modular cooling pallet frame 500 to the cooling system. Since the cooling fluid delivered by fluid return line 502 may be hot, the cooling system may cool the cooling fluid received by fluid return line 502, so that it can be used again by fluid supply line 501. In some embodiments, the cooling fluid may be water or other refrigerant.

Any suitable number of fluid supply lines and fluid return lines may be attached to modular cooling pallet frame 500. In some cases, there may be one supply line and one fluid return line, such as fluid supply line 501 and fluid return line 502, that connect from the source storing cooling fluid to modular cooling pallet frame 500. In some embodiments, as shown in FIG. 5, fluid supply line 501 may be split into multiple supply lines (e.g., 501A and 501B) at modular cooling pallet frame 500 so that each of the multiple supply lines leads to a certain section of slanted surface 510 on which a cooling module may be attached. Similarly, fluid return line 502 may be split into multiple return lines (e.g., 502A and 502B) at modular cooling pallet frame 500 so that each of the multiple return lines connects from a certain section of slanted surface 510 on which a cooling module may be attached.

In some embodiments, fluid supply line 501 and fluid return line 502 may also deliver and remove cooling fluid for cooling modules attached to slanted surface 520. In other embodiments, there may be additional fluid supply lines besides fluid supply line 501 and fluid return line 502 that deliver and remove cooling fluid for cooling modules attached to slanted surface 520. Further, in other embodiments, there may be multiple fluid supply lines and fluid return lines that can deliver cooling fluid to and remove cooling from a single cooling module.

A modular cooling pallet comprising a modular cooling pallet frame and cooling modules as described above enables computers in a data center to be cooled according to their individual air conditioning needs. For example, a first group of cooling modules may direct cold air downwards towards a first group of computers and a second group of cooling modules may direct cold air downwards towards a second group of computers within the data center. If the first group of computers is generating more heat than the second group of computers, then the first group of cooling modules may provide more powerful air conditioning than that provided by the second group of cooling modules. This can allow the first group of computers to be cooled to an appropriate temperature independent of the cooling needs of the second group of computers. Hence, the modular cooling system enables a way to provide an effective and customized cooling processes for data centers.

In addition, a modular cooling pallet may be configured with an interchangeable cooling module feature, which provides an efficient and convenient way to regulate a cooling system for a data center. A modular cooling pallet can be created with a customized combination of cooling modules of different sizes and different cooling properties, which enables the modular cooling pallet to provide the proper cooling capability for computers of the data center without wasting unnecessary energy. Further, the configuration of a modular cooling pallet is not permanent and can be easily altered to accommodate for changes in cooling needs. This is because individual cooling modules can be interchanged with other cooling modules or unpopulated areas even after assembly into the original configuration of the modular cooling pallet.

In some embodiments, the modular housing described with respect to FIG. 1 that encloses the modular cooling system and data center described above can be assembled using modular assembly components. In contrast to typical containerized solutions that are pre-built, which can be limiting in size and flexibility, the modular housing can be assembled at the operating site utilizing modular building blocks.

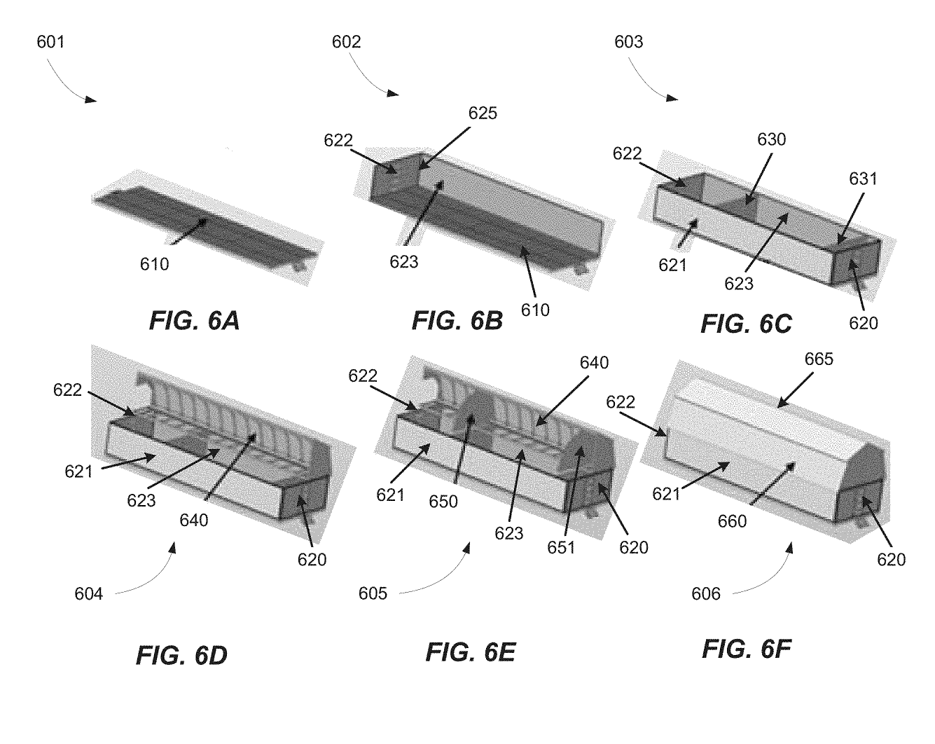

FIG. 6A-6F shows the assembly of a modular housing according to embodiments of the invention. The modular housing may house a data center and a modular cooling system as described above. The modular housing may comprise a plurality of roof structures 640 and 660 and a plurality of connectable walls structures 620, 621, 622, and 623 that may be assembled to form an enclosure housing the data center and the modular cooling system. There may also be a floor structure 610 on which racks and computers may be placed within the modular housing. In some embodiments, the modular housing may also comprise internal partition panels 630, 631, 650, and 651.

The components of the modular housing may provide features that allow the modular housing to be assembled without the use of additional or loose fasteners, making it possible to quickly assemble the modular housing at any site. For example, the components of the modular housing may be embedded with fastening features that can be used to attach the components together.

The embedded fastening features may comprise cam-lock assembly parts. The cam-lock assembly parts may include cams and receptacles, where a cam and receptacle can latch together. In some cases, the cam may be a metal structure with a semicircular shaped arm device that may gradually increase in thickness around its arc. The receptacle may be a metal structure that accepts entry of the cam. As the cam is rotated within the receptacle, the cam may enter the receptacle. The increasing thickness of the cam can create a mechanical pull on the receptacle, which tightly pulls together the cam and the receptacle. This can fasten a component embedded with the cam and a component embedded with the receptacle. In addition, it is possible to unlatch the cam and receptacle after being fastened together. Rotating the cam in the direction opposite from that used to latch the cam and receptacle together can release the cam from the receptacle. This provides the ability to disassemble certain components fastened by cams and receptacles as desired. Rotating a cam may be performed using a single mechanical tool that can interface with the cam.

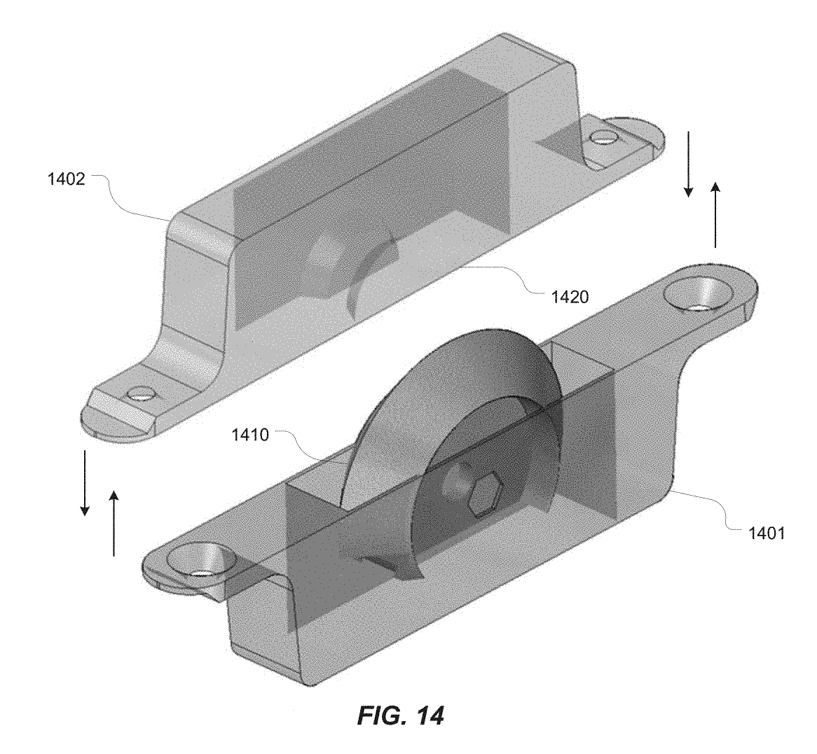

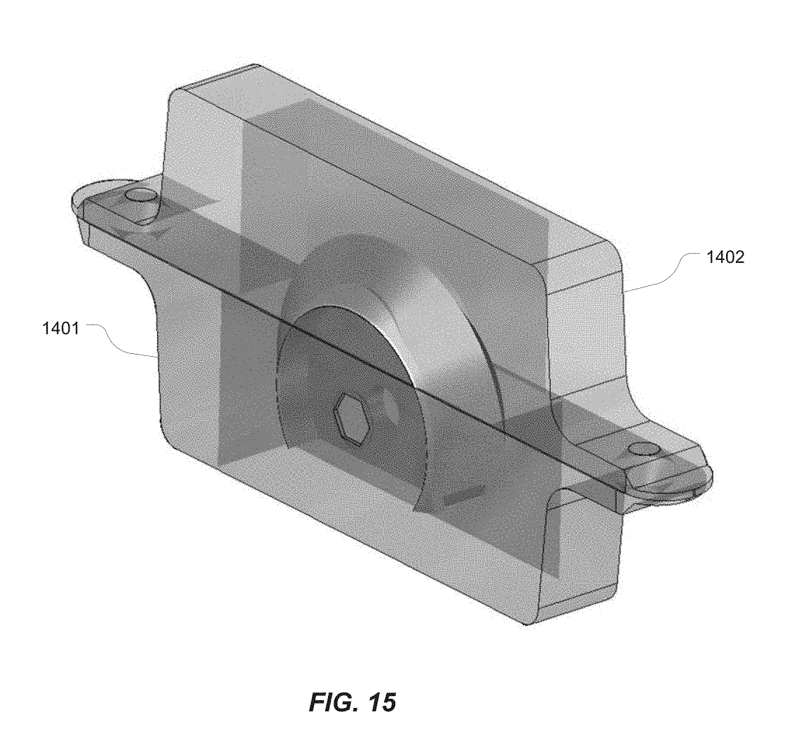

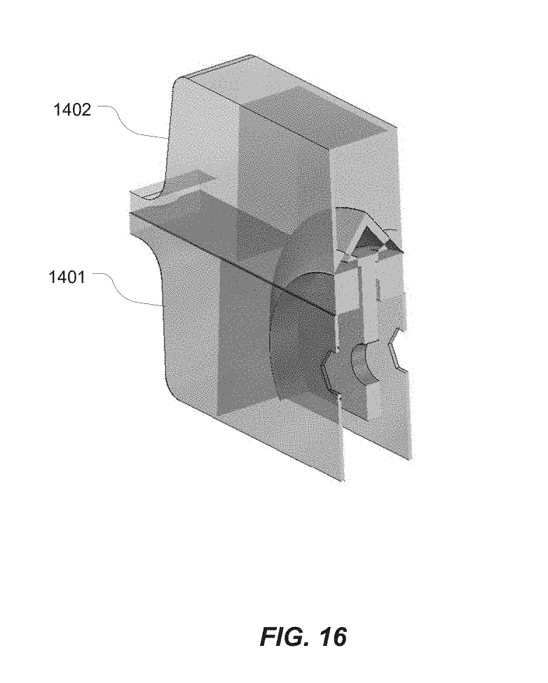

Close up views of exemplary cam-lock assembly parts 1401 and 1402 are shown in FIG. 14-16 according to embodiments of the invention. As shown in FIG. 14, cam-lock assembly part 1401 includes a cam 1410 and cam-lock assembly part 1402 includes a receptacle 1420. The cam-lock assembly parts 1401 and 1402 can be fastened together such that cam 1401 latches to receptacle 1420, as shown in FIG. 15. FIG. 16 shows a cross-section of the fastened cam-lock assembly parts 1401 and 1402.

Cam-lock assembly parts comprising cams and receptacles may be positioned along the edges of wall structures 620, 621, 622, and 623, floor structure 610, and roof structures 640 and 660. Corresponding cams and receptacles may be positioned in opposing locations that allow them to mate as wall structures 620, 621, 622, and 623, floor structure 610, and roof structures 640 and 660 are placed into position. The process of assembling the modular housing using these fastening features is described below.

While an implementation using cam-lock assembly parts for fastening is described in detail herein, it is understood that other suitable fasteners may be used instead of cam-lock assemblies for the modular housing. Other suitable fasteners that can be used include mortise and tenon joints, pin joints, interlocking joints, self-fixturing joints, bolted joints (e.g., rivet nuts, bolts, and screws), lap joints, biscuit joints, and clamped joints.

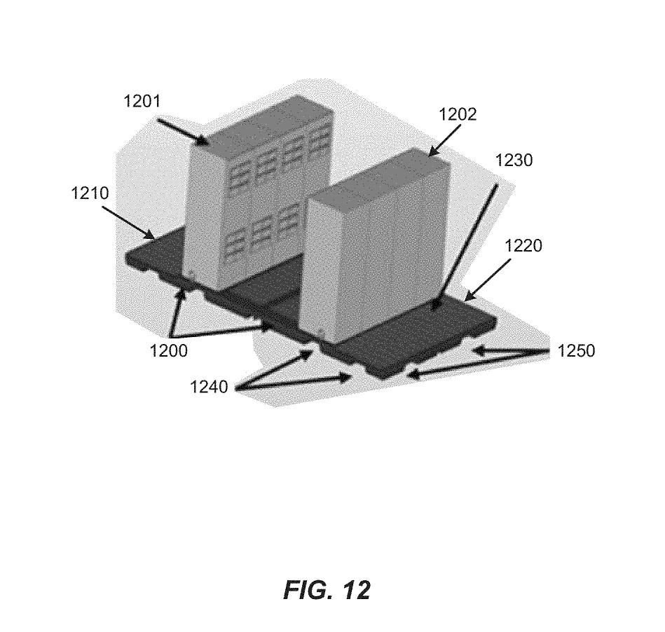

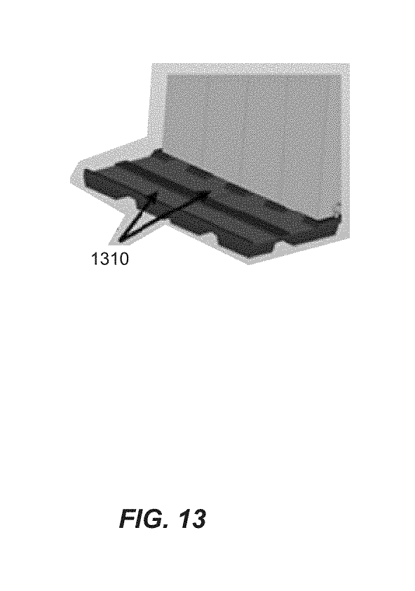

At step 601, a floor structure 610 may be placed as the base of the modular housing. In some embodiments, floor structure 610 may comprise multiple floor sections in the form of one or more rack pallets, which are described in more detail with respect to FIG. 12 and FIG. 13. In some cases, floor structure 610 may be made of a durable plastic. Floor structure 610 may be designed to support the weight of the computers, racks, and the modular cooling system that are to be placed on top of the floor structure 610.

At step 602, wall structures 622 and 623 may be erected upwards perpendicular to floor structure 610. Wall structures 622 and 623 may be attached to floor structure 610 using fastening features provided by the modular housing. Additionally, wall structures 622 and 623 may be attached to each other along a shared edge 625 using the fastening features provided by the modular housing.

Wall structures 622 and 623 may be attached along their bottom edges to floor structure 610. In some embodiments, there may be cams positioned along the edges of floor structure 610 and receptacles, corresponding to the cams, positioned along the bottom edges of wall structures 622 and 623 that are to be attached to floor structure 610. When wall structures 622 and 623 are placed into position relative to floor structure 610, the cams and receptacles may mate and thus fasten wall structures 622 and 623 to floor structure 610.

While one exemplary embodiment is described above regarding positioning of cams and receptacles on wall structures 622 and 623 and floor structure 610, embodiments are not so limited. In some implementations, there may be receptacles positioned along the edges of floor structure 610 and cams, corresponding to the receptacles, positioned along the bottom edges of wall structures 622 and 623 that are to be attached to floor structure 610. In other implementations, there may be a combination of cams and receptacles positioned along the edges of floor structure 610 and a corresponding combination of receptacles and cams positioned along the bottom edges of wall structures 622 and 623 that are to be attached to floor structure 610. Any suitable combination of cams and receptacles may be used so that the cams and receptacles that come into contact with each other when wall structures 622 and 623 are placed into position relative to floor structure 610 are compatible and can latch together, which fastens wall structures 622 and 623 to floor structure 610.

Further, adjacent wall structures 622 and 623 may be attached to each other along shared edge 625. For example, cams and receptacles may be positioned along the shared edge 625 to fasten together adjacent wall structures 622 and 623. An exemplary configuration for fastening wall structure 622 to wall structure 623 is that there may be cams positioned along the shared edge 625 of wall structure 622 and receptacles, corresponding to the cams, positioned along the shared edge 625 of wall structure 623. When adjacent wall structures 622 and 623 are placed into position, the cams and corresponding receptacles can mate and latch together to fasten wall structures 622 and 623 together.

While one exemplary embodiment is described above regarding positioning of cams and receptacles along shared edge 625 between wall structure 622 and wall structure 623, embodiments are not so limited. In some implementations, there may be receptacles positioned along the shared edge 625 of wall structure 622 and cams, corresponding to the receptacles, positioned along the shared edge 625 of wall structure 623. In other implementations, there may be a combination of cams and receptacles positioned along the shared edge 625 of wall structure 622 and a corresponding combination of receptacles and cams positioned along the shared edge 625 of wall structure 623. Any suitable combination of cams and receptacles may be used so that the cams and receptacles that come into contact with each other when adjacent wall structures 622 and 623 are placed into position are compatible and can latch together, which fastens wall structures 622 and 623 together.

At step 603, wall structures 620 and 621 may be erected upwards perpendicular to floor structure 610. Wall structures 620 and 621 may be attached to floor structure 610 using fastening features provided by the modular housing. Additionally, each of wall structures 620, 621, 622, and 623 may be attached to its adjacent wall structures using the fastening features provided by the modular housing.

Wall structures 620 and 621 may be attached along their bottom edges to floor structure 610. In some embodiments, there may be a combination of cams and receptacles positioned along the edges of floor structure 610 and a corresponding combination of receptacles and cams positioned along the bottom edges of wall structures 620 and 621 that are to be attached to floor structure 610. When wall structures 620 and 621 are placed into position relative to floor structure 610, the cams on floor structure 610 may mate with the receptacles on the bottom edges of wall structures 620 and 621 and the receptacles on floor structure 610 may mate with the cams on the bottom edges of wall structures 620 and 612. This may fasten wall structures 620 and 621 to floor structure 610.

Further, each of wall structures 620, 621, 622, and 623 may be attached to its adjacent wall structures. Each of wall structures 620, 621, 622, and 623 may be adjacent to and share edges with two other wall structures. Hence, each wall structure may be attached to two other wall structures. For example, wall structure 620 may be fastened to adjacent wall structures 621 and 623, wall structure 621 may be fastened to adjacent wall structures 622 and 620, wall structure 622 may be fastened to adjacent wall structures 623 (described in step 602) and 621, and wall structure 623 may be fastened to adjacent wall structures 620 and 622 (described in step 602).

Cams and receptacles may be positioned along the shared edges between adjacent pairs of wall structures 620, 621, 622, and 623 for attaching each wall structure to its adjacent wall structures. In some embodiments, similar configurations of cams and receptacles described above with respect to shared edge 625 for fastening wall structures 622 and 623 may be positioned along the remaining shared edges between wall structures 620 and 621, wall structures 621 and 622, and between wall structures 620 and 623. Hence, when wall structures 620 and 621 are placed into position, the cams and receptacles along the shared edges may mate and enable adjacent wall structures among wall structures 620, 621, 622, and 623 to be latched together.

While the steps for attaching each of wall structures 620, 621, 622 and 623 to floor structure 610 and to its adjacent wall structures are described above as being performed in an orderly manner, embodiments are not so limited. For example, wall structures 620, 621, 622 and 623 may be erected in any suitable order. Additionally, each of wall structures 620, 621, 622 and 623 may be fastened to floor structure 610 and to its adjacent wall structures in any suitable order. In some cases, some of the steps for fastening each of wall structures 620, 621, 622 and 623 to floor structure 610 and to its adjacent wall structures may be performed in parallel.

In some embodiments, a plurality of internal partition panels, such as internal partition panels 630 and 631, may be positioned inside the modular housing. Internal partition panels 630 and 631 may be used to section off certain areas within the modular housing. For example, the internal partition panels 630 and 631 may be used to separate areas in the data center with racks and computers associated with different entities. Internal partition panels 630 and 631 may also prevent hot air streams produced by computers associated with one entity from traveling into other areas within modular housing that may house computers associated with a different entity.

At step 604, roof structure 640 may be placed into position on top of wall structures 620, 622, and 623. In some embodiments, roof structure 640 may be lifted and placed into position with a crane. In some cases, roof structure 640 may comprise a plurality of panels and may make up half of a barn style roof. It is understood that in other cases, other suitable roof styles may be utilized for the modular housing, such as a single pitch style roof or a flat style roof.

Fastening features provided by the modular housing may enable roof structure 640 to be fastened to other components of the modular housing. Any suitable combination of cams and receptacles may be embedded along the bottom edges of roof structure 640 to enable fastening of roof structure 640 to wall structures 620, 622, and 623. A corresponding combination of receptacles and cams may be embedded along the top edges of wall structures 620, 622, and 623 to which roof structure 640 is to be attached. When roof structure 640 is placed into position, the cams and receptacles along the bottom edges of roof structure 640 may mate with the receptacles and cams embedded along the top edges of wall structures 620, 622, and 623. This can fasten roof structure 640 on top of wall structures 620, 622, and 623.

In some embodiments, roof structure 640 may be lined internally with a support structure. The support structure may comprise support beams that may be positioned equidistant from each other along the inside of roof structure 640. In some cases, the support structure may enable positioning and fastening of internal partition panels, such an internal partition panel 650 and 651, within the modular housing, as described in step 605.

At step 605, internal partition panels 650 and 651 may be attached to roof structure 640. Internal partition panels 650 and 651 may be a suitable size so that they can fit beneath roof structure 640 and above wall structure 620, 621, 622, and 623. In some embodiments, internal partition panels 650 and 651 may be positioned directly above internal partition panels 630 and 631, respectively. In some cases, internal partition panels 650 and 651 may be used to separate areas in the data center with racks and computers associated with different entities. Internal partition panels 650 and 651 may also prevent hot air streams produced by computers associated with one entity from traveling into other areas within modular housing that may house computers associated with a different entity.

Internal partition panels 650 and 651 may be attached to the support structure of roof structure 640 using fastening features provided by the modular housing. The support structure lining the inside of roof structure 640 may be embedded with a combination of cams and receptacles. Internal partition panels 650 and 651 may also be embedded with a corresponding combination of receptacles and cams along their outer edges. When internal partition panels 650 and 651 are placed into position beneath roof structure 640, the cams and receptacles embedded along the outer edges of internal partition panel 650 and 651 that come into contact with the receptacles and cams of the support structure may latch together. It is noted that internal partition panels 650 and 651 may be fastened along any of the support beams lining the inside of roof structure 640 and thus are not limited to their positions shown in FIG. 6A-6F.

At step 606, roof structure 660 may be placed into position on top of wall structures 620, 621, and 622. In some embodiments, roof structure 640 may also be lifted and placed into position with a crane. In some embodiments, roof structure 660 may comprise a plurality of panels and make up the other half of the barn style roof. While not shown in FIG. 6A-6F, roof structure 660 may be lined internally with a support structure similar to that of roof structure 640.

Fastening features provided by the modular housing may enable roof structure 660 to be fastened to other components of the modular housing. For example, any suitable combination of cams and receptacles may be embedded along the bottom edges of roof structure 660 to enable fastening of roof structure 660 to wall structures 620, 621, and 622. A corresponding combination of receptacles and cams may be embedded along the top edges of wall structures 620, 621, and 622. When roof structure 660 is placed into position on top of wall structures 620, 621, and 622, the cams and receptacles along the bottom edges of roof structure 660 may mate with the receptacles and cams embedded along the top edges of wall structures 620, 621, and 622. This can fasten roof structure 640 to wall structures 620, 621, and 622. Further, internal partition panels 650 and 651 may be fastened to the support structure lining the inside of roof structure 660 (not shown) by a process similar to that described with respect to step 605.

In addition, roof structure 660 may be attached to roof structure 640 along shared edge 665. Any suitable combination of cams and receptacles may be embedded along the shared edge 665 of roof structure 660 to enable fastening of roof structure 660 to roof structure 640. A corresponding combination of receptacles and cams may be embedded along the shared edge 665 of roof structure 640. When roof structure 660 is placed into position, the cams and receptacles along the shared edge 665 of roof structure 640 may mate with the receptacles and cams embedded along the shared edge 665 of roof structure 660. This can fasten roof structure 640 to roof structure 660 to complete assembly of the modular housing.

While the steps for attaching roof structures 640 and 660 to wall structures 620, 621, 622, and 623, internal partition panels 650 and 651, and to each other are described above as being performed in an orderly manner, embodiments are not so limited. The fastening steps may be performed in any suitable order. In some cases, some of the fastening steps may be performed in parallel.

Features of the modular housing provide several advantages. For example, the components of the modular housing may be factory built and can be embedded with fastening features. This eliminates the need for additional or loose fasteners for assembling the modular housing, which enables a quick and simple assembly of the modular housing on site with use of just a couple of tools.

Additionally, while the fastening features of the modular housing can provide sturdy fastening of components, the modular housing may be disassembled if desired. For example, the cam and receptacle features used to attach components in steps 601 to 606 may be unlatched by rotating the cam out of the receptacle. Thus, assembly and disassembly of the modular housing can be performed multiple times, which provides the ability to relocate components of the modular housing and reassemble the modular housing in a new location. The ability to disassemble the modular housing may make the process of relocating the modular housing more flexible, since components of the modular housing may be transported separately. This can eliminate the issues that can come with having to transport a fully assembled modular housing, which can be large, bulky, and an inefficient use of transportation space.

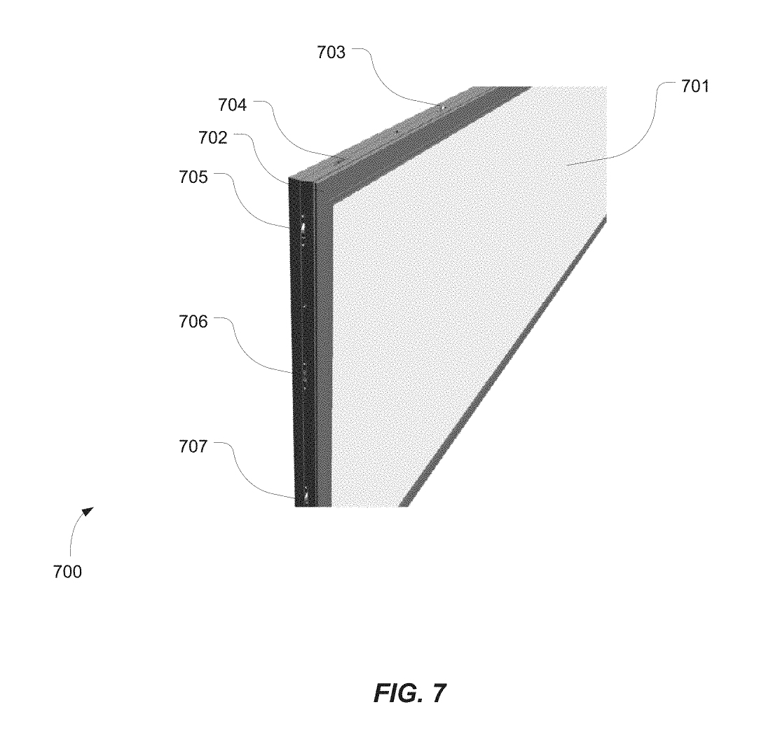

FIG. 7 shows a close up of wall structure 700 according to embodiments of the invention. Wall structure 700 includes a panel 701, an extrusion 702, and cam-lock assembly parts 703, 704, 705, 706, and 707. Panel 701 may make up the body of wall structure 700 and may be made of a fiberglass composite. Panel 701 may be glued into extrusion 702, which may be made out of aluminum.

In other embodiments, panel 701 and extrusion 702 may be made out of other suitable materials. For example, panel 701 may be made out of other types of fiber-reinforced plastics, such as carbon fiber reinforced plastic. In some cases, the composite may comprise any suitable mixture of various types of fibers, which may include one or more of fiberglass, aluminum, carbon, and aramid fibers. In addition, extrusion 702 may be made out of other suitable metals, such as steel or other alloys.

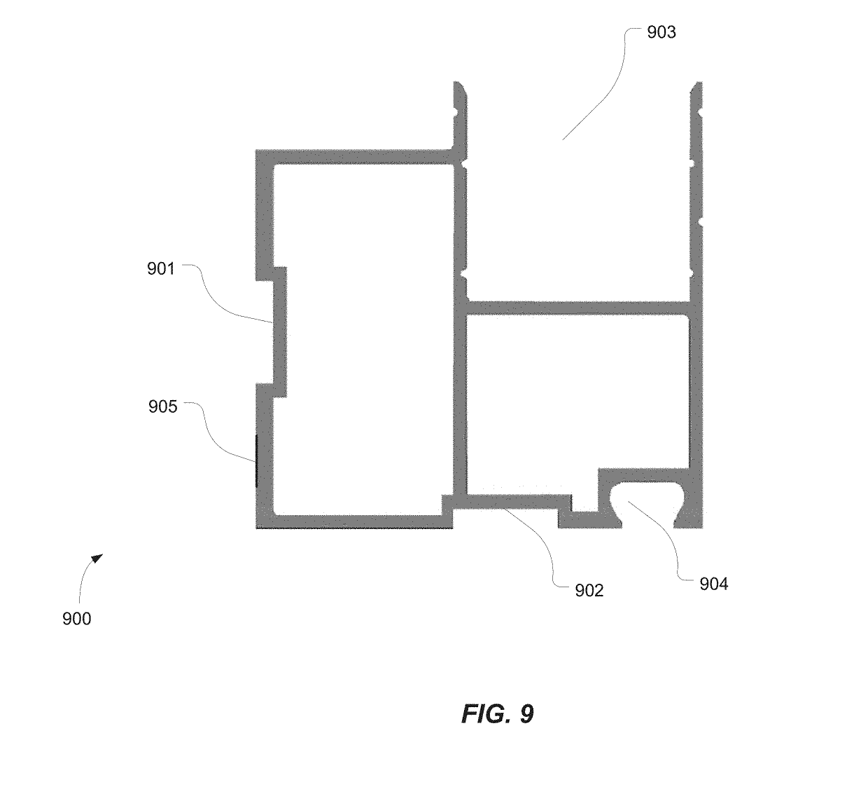

The outer edge of wall structure 700 may be embedded with cam-lock assembly parts (e.g., 703, 704, 705, 706, and 707). The cam-lock assembly parts may alternate between those comprising cams (703, 705, and 707) and those comprising receptacles (704 and 706). The cam-lock assembly parts can be used to fasten wall structure 700 to other components of a modular housing. While the full wall structure 700 is not shown in FIG. 7, cam-lock assembly parts may be embedded along all of the outer edges of wall structure 700. The customized design of extrusion 702 is described in more detail with respect to FIG. 9.

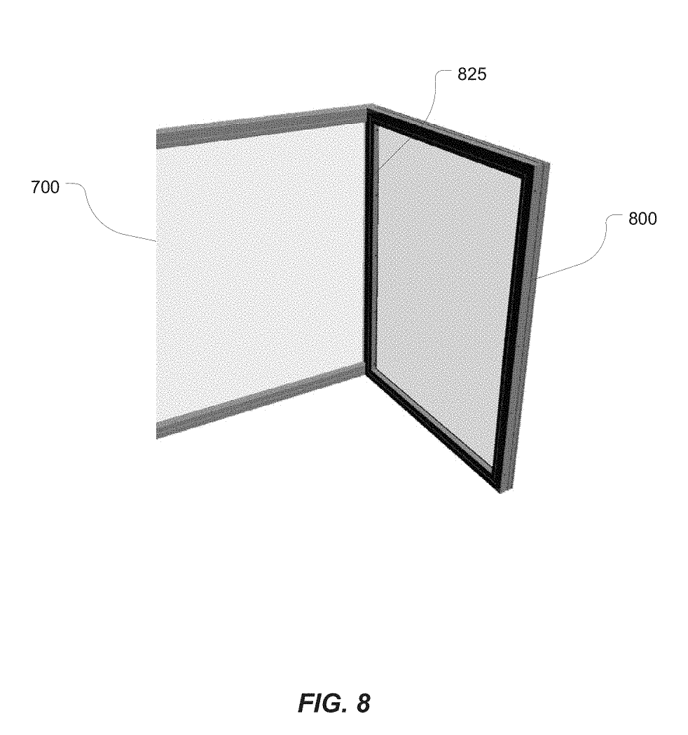

FIG. 8 shows adjacent wall structures 700 and 800 fastened together according to embodiments of the invention. Wall structure 700 and wall structure 800 may share edge 825, along which cams and receptacles may be latched together. Each cam may correspond to receptacle to which it can be fastened. In some embodiments, there may be a combination of cams and receptacles positioned along shared edge 825 on wall structure 700 and a corresponding combination of receptacles and cams positioned along shared edge 825 on wall structure 800. The cams positioned along shared edge 825 on wall structure 700 may be compatible with receptacles positioned along shared edge 825 on wall structure 800 and may mate when joined together. Additionally, the receptacles positioned along shared edge 825 on wall structure 700 may be compatible with cams positioned along shared edge 825 on wall structure 800 and may mate when joined together.

In one exemplary case, alternating cams and receptacles similar to those of cam-lock assemblies 705, 706, and 707 shown in FIG. 7 may be positioned along shared edge 825 on wall structure 700. In this case, alternating receptacles and cams opposing those on wall structure 700 may be positioned along shared edge 825 on wall structure 800. Each of the cams embedded along shared edge 825 on wall structure 700 may be positioned so that it aligns with a receptacle embedded along shared edge 825 on wall structure 800. Each of the receptacles embedded along shared edge 825 on wall structure 700 may also be positioned so that it aligns with a cam embedded along shared edge 825 on wall structure 800. Accordingly, when adjacent wall structure 700 and wall structure 800 are placed together, aligned cams and receptacles may be fastened to connect wall structure 700 and wall structure 800 together.

FIG. 9 shows an extrusion profile of an extrusion 900 of a wall structure according to embodiments of the invention. The extrusion profile may be a top section view of extrusion 900 that can be attached to a panel to create a wall structure of a modular housing. The extrusion 900 may be designed specifically for a modular housing that can be assembled without additional or loose fasteners as described above. FIG. 9 also includes cam-lock grooves 901 and 902, a panel pocket 903, a gasket pocket 904, and a gasket seal contact surface 905.

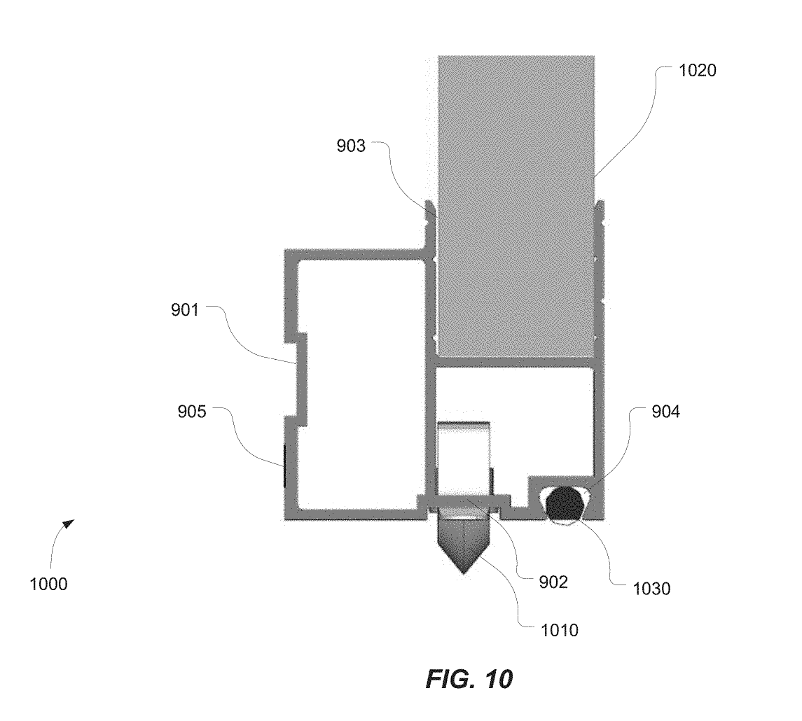

Cam-lock grooves 901 and 902 may be indentations in extrusion 900 that are configured to hold cam-lock assembly parts, including those comprising cams or receptacles. The cam-lock grooves 901 and 902 enable a cam-lock assembly part to be mounted within the extrusion of the wall structure. The cam-lock grooves 901 and 902 can provide adequate clearance space so that neither the cams nor receptacles of the cam-lock assembly parts interfere with other components (e.g., adjacent wall structures, floor structures, roof structures, etc.) being connected to the wall structure when assembling the modular housing. In some embodiments, not all cam-lock grooves of extrusion 900 may be occupied with cam-lock assembly parts. For example, as shown in FIG. 10, which shows a top section view of an assembled wall structure 1000, cam-lock groove 901 may not be occupied, while cam-lock groove 902 may be occupied by a cam-lock assembly part 1010 comprising a cam.

Panel pocket 903 may be an opening in extrusion 900 that is cooperatively structured to hold a panel of a wall structure. In some embodiments, the panel pocket 903 may have a suitable width so that the end of the panel may be inserted into and securely attached to panel pocket 903. As shown in FIG. 10, a panel 1020 of a wall structure 1000 may be inserted into panel pocket 903. In some embodiments, panel 1020 may be glued into panel pocket 903.

Gasket pocket 904 may be an area that is configured to hold a gasket within extrusion 900. The gasket may be inserted into gasket pocket 904, which may be able to hold the gasket in its proper place when the wall structure is an independent structure that is not yet connected to other components (e.g., adjacent wall structures, floor structures, roof structures, etc.) of the modular housing. This eliminates the need to keep track of loose gaskets when transporting the wall structure for assembly at another site.

As shown in FIG. 10, a gasket 1030 may be held in place by gasket pocket 904. Gasket 1030 may be of any suitable shape and material such that it can create an environmental seal. In some embodiments, gasket 1030 may have a round shape (e.g., O-ring) and may be made of an elastomer. In other embodiments, gasket 1030 may be made from other materials, such as cork, glass, metal, or silicone. However, it is understood that an appropriate type of gasket 1030 may be selected based on a variety of factors, including application temperature, sealing pressure, permeability, durability of material, size, and cost.

Gasket pocket 904 may also provide an appropriate amount of space for compression of the gasket when the wall structure is fastened to another component of the modular housing. For example, when the wall structure is fastened to another component of the modular housing, such as an adjacent wall structure, the gasket may be compressed against the extrusion of the adjacent wall structure. The compressed gasket may seal the space between the wall structure associated with the gasket and the adjacent wall structure, so that the internal environment within the wall structures is sealed from the environment external to the wall structures. Thus, the gasket feature of the extrusion may seal the environment within the modular housing from air, water, or other fluids that may be present in the environment external to the modular housing.

Gasket seal contact surface 905 may be the surface against which a gasket may be compressed. For example, a gasket from another component of the modular housing may be compressed against gasket seal contact surface 905. Gasket seal contact surface 905 may be configured to have a certain roughness in order to create a level of friction between the compressed gasket and gasket seal contact surface 905. In some embodiments, a series of straight or concentric grooves may be created on gasket seal contact surface 905 to produce a rough surface.

In some cases, the roughness of gasket seal contact surface 905 may have an effect on creep and relaxation of the gasket. Thus, depending on the type of gasket utilized, a different roughness may be optimal for gasket seal contact surface 905 to optimize the effectiveness of the gasket. For example, a nonmetallic gasket, such as a rubber gasket, may be more susceptible to creep and relaxation when under a load. This can result in potential leakage and ineffectiveness of the gasket seal. Thus, a rougher surface for gasket seal contact surface 905 may generally be more effective for this soft gasket to create sufficient friction between fastened components of the modular housing.

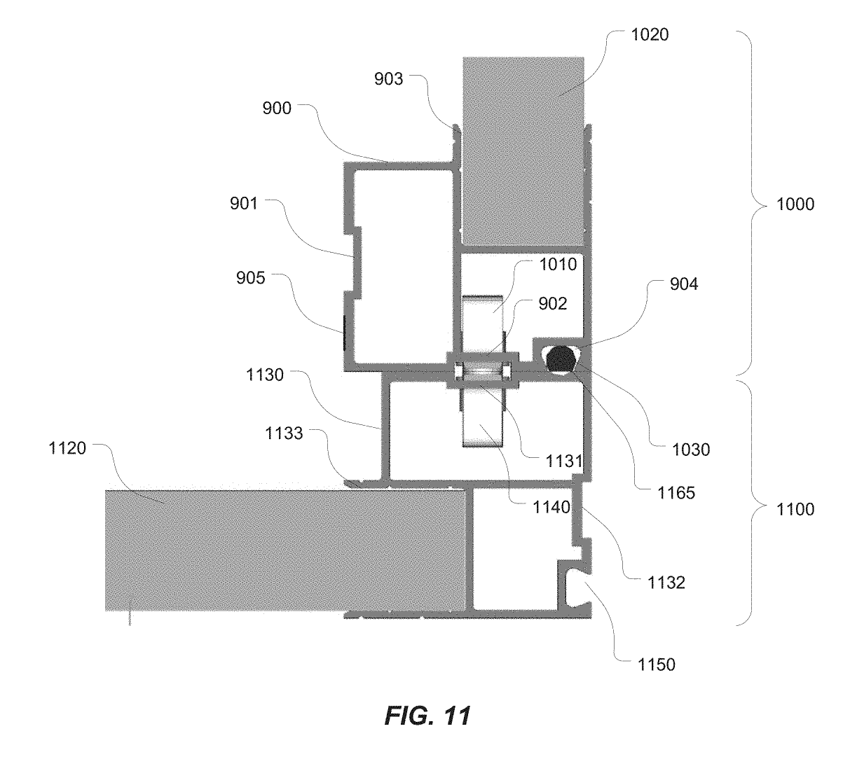

FIG. 11 shows a top section view of a corner formed by attaching adjacent wall structures 1000 and 1100 according to embodiments of the invention. As described with respect to FIG. 9 and FIG. 10, wall structure 1000 may comprise panel 1020 attached to panel pocket 903 of extrusion 900, a gasket 1030 in gasket pocket 904, a gasket seal contact surface 905, and cam-lock grooves 901 and 902, where cam-lock groove 902 is occupied by cam-lock assembly part 1010 comprising a cam. Wall structure 1100 may comprise a panel 1120 attached to panel pocket 1133 of extrusion 1130, a gasket pocket 1150, a gasket seal contact surface 1165, and cam-lock grooves 1131 and 1132, where cam-lock groove 1131 is occupied by a cam-lock assembly part 1140 comprising a receptacle.

When wall structures 1000 and 1100 are placed together, they may be fastened together by the cam of cam lock assembly part 1010 of wall structure 1000 and the receptacle of cam-lock assembly part 1140 of wall structure 1100. The cam of cam lock assembly part 1010 and the receptacle of cam-lock assembly part 1140 may be able to mate and latch together. A single mechanical tool may be utilized to interface with the cam and rotate it into the receptacle, which accepts the cam. This process can fasten the cam and receptacle together and thus wall structures 1000 and 1100 together without the use of additional or loose fasteners. While one exemplary configuration is described above, in other embodiments, cam-lock groove 902 of wall structure 1000 may hold the receptacle and cam-lock groove 1131 of wall structure 1100 may hold the cam.

Fastening wall structures 1000 and 1100 may compress gasket 1030 against gasket seal contact surface 1165. This creates a seal between wall structures 1000 and 1100 and prevents leakage between the internal and external environment relevant to wall structures 1000 and 1100. Similarly to gasket seal contact surface 905 described above with respect to FIG. 10, gasket seal contact surface 1165 may be a rough surface designed to create a level of friction between gasket 1030 and gasket seal contact surface 1165. This may help prevent creep and relaxation of gasket 1030 when under a load.

It is noted that certain features of extrusion 900 of wall structure 1000 and extrusion 1130 of wall structure 1100 may not be utilized for the particular attachment of adjacent wall structures 1000 and 1100 depicted in FIG. 11. For example, cam-lock groove 901, gasket seal contact surface 905, cam-lock groove 1132, and gasket pocket 1150 may be unoccupied for this particular attachment of adjacent wall structures 1000 and 1100.

These unused features are the result of the use of adaptable and uniform extrusion structures that can be utilized to connect components of the modular housing. For example, even though the directions in which wall structures 1000 and 1100 are to be fastened differ, similar extrusion structures may be utilized for wall structures 1000 and 1100. Each extrusion is configured to provide two attachment areas, one comprising an area to hold a cam-lock assembly part and a gasket (e.g., cam-lock groove 902 and gasket pocket 904 of wall structure 1000, and cam-lock groove 1132 and gasket pocket 1150 of wall structure 1100), and the other comprising an area to hold an opposing cam-lock assembly part and a surface on which a gasket can be compressed (e.g., cam-lock groove 901 and gasket seal contact surface 905 of wall structure 1000, and cam-lock groove 1131 and gasket seal contact surface 1165 of wall structure 1100). By using these extrusions, wall structures 1000 and 1100 are able to provide fastening features on either of the two attachment areas by simply installing cam-lock assembly parts and gaskets into the appropriate cam-lock grooves and gasket pockets. Since it is not necessary to utilize different types of extrusion structures for wall structures that are to be attached to other components in a certain direction, the uniformity of the extrusion structures provides a more flexible and simple assembly of the modular housing.

While the fastening of adjacent wall structures is described in detail above, it is understood that similar structures and methods may be utilized to connect other components of the modular housing. These other connections may include, but are not limited to, connection between other adjacent wall structures, between wall structures and a floor structure, and between wall structures and roof structures.

FIG. 12 shows a rack pallet 1200 according to embodiments of the invention. Rack pallet 1200 may be part of a floor structure of a modular housing. Rack pallet 1200 solves certain issues faced with construction of a data center, which may be enclosed within the modular housing.

Typically, construction of a data center utilizes standard 19-inch rack assemblies on which various electronics are installed. Since a data center usually hosts a large number of the 19-inch racks full of electronic equipment, assembly of these electronics with appropriate wiring on site can bring about various issues. On top of being labor intensive, the assembly of the electronics can have inconsistent wiring from site to site, which makes the assembly process error-prone. This is inefficient, since there can result in a need for additional rounds of testing and reworking of electrical connections.

Rack pallet 1200 solves these issues by providing features that allow for a plurality of 19-inch racks to be populated with various electronics that can be pre-wired and tested in factory. Factory assembly and testing of electrical connections eliminates significant labor typically needed to assemble a data center on an operating site, as well as improves the quality of the product delivered to the operating site. Since rack pallet 1200 can be preinstalled with integrated data center equipment, this simplifies the assembly of the modular housing comprising the data center. An exemplary assembly of rack pallet 1200 with data center electronics is described below.

Rack pallet 1200 may be part of a floor structure of a modular housing. In some embodiments, rack pallet 1200 may be a two-piece assembly that connects a first half 1210 and a second half 1220. Rack pallet 1200 may be configured such that any suitable number of rack pallets may be connected adjacent to racket pallet 1200. Multiple adjacent rack pallets combined may serve as the floor structure of the modular housing. Rack pallet 1200, along with adjacent rack pallets, may support a plurality of wall structures that are a part of the modular housing.

A plurality of 19-inch racks may be placed on top of rack pallet 1200. In some cases, there may be a first row 1201 of four adjacent 19-inch racks and a second row 1202 of four adjacent 19-inch racks. The 19-inch racks may be stabilized by being wired to the bottom of rack pallet 1200. The 19-inch racks may be pre-assembled in the factory with various electronics, which may comprise servers, switches, memory storage devices, and other data center electronics. When multiple adjacent rack pallets are combined together as described above, one or more longer rows of adjacent 19-inch racks may be formed on top of the rack pallets.

Rack pallet 1200 be configured to receive a plurality of wires that may be electrically coupled to computers in the first row 1201 of four adjacent 19-inch racks and the second row 1202 of four adjacent 19-inch racks. Rack pallet 1200 may enable the plurality of wires to be passed underneath the top surface of rack pallet 1200. For example, there may be wire ways underneath the top surface of rack pallet 1200 through which wires for signal and power connections for the electronics can be routed. A close up of the location of exemplary wire ways 1310 are shown in FIG. 13. In some embodiments, some wires fed through wire ways 1310 may be designated for power connections to adjacent rack pallets and some wires fed through wire ways 1310 may be designated for signal connections to adjacent rack pallets.

Rack pallet 1200 may also have a grating 1230 that covers the wires that pass underneath the top surface of rack pallet 1200. The grating 1230 can prevent the wires from being exposed above rack pallet 1200 where people may walk. Thus, the grating 1230 can prevent potential damage cause by people stepping on the wires.

Rack pallet 1200 may also provide forklift pockets that enable a forklift to maneuver rack pallet 1200. Rack pallet 1200 may comprise front forklift pockets 1240 and side forklift pockets 1250. These forklift pockets may be used by a forklift to lift and move rack pallet 1200, which may have the 19-inch racks and data center electronics installed on it. This enables rack pallet 1200 to be simply slid into the modular housing during assembly.

The structure of rack pallet 1200 provides several advantages. For example, the wire ways provided by rack pallet 1200 keep wires organized and in place, which may reduce the risk of wires becoming disconnected or damaged. The wire ways can also keep the wires out of the way of people that may walk on rack pallet 1200, which is safer and can further prevent potential damage to the wires.

In addition, rack pallet 1200 is designed so that when multiple rack pallets are combined as described above, wiring can be routed from any of the 19-inch racks to another 19-inch rack through the wire ways. For example, when multiple rack pallets are combined, the wire ways between adjacent rack pallets may be aligned. The aligned wire ways can thus route connections between the adjacent rack pallets (not shown). The wire ways may also route connections to the main power or communications sources of the data center facility by designating certain wire ways for power connections and signal connections. Since the electrical wiring of the electronic equipment between rack pallets can be pre-assembled at the factory, the wiring that occurs at the operating site of the data center at which the modular housing is assembled is simplified. It is noted that rack pallet 1200 does not have to be utilized in a modular housing as described herein in order to provide these features and may also be utilized in other data center environments.

As described herein, the features of the modular housing provide the ability to incrementally install prefabricated modules of equipment. This enables quick assembly of the modular housing comprising a data center on site, which is not possible in typical containerized solutions that have to be fully integrated at once. Additionally, since the modular housing enables the use of embedded fastening features and pre-wired racks comprising electronic equipment, the modular housing can be assembled using just a couple of tools. This further simplifies the assembly process of the modular housing.

The above description is illustrative and is not restrictive. Many variations of the invention will become apparent to those skilled in the art upon review of the disclosure. The scope of the invention should, therefore, be determined not with reference to the above description, but instead should be determined with reference to the pending claims along with their full scope or equivalents.

One or more features from any embodiment may be combined with one or more features of any other embodiment without departing from the scope of the invention.

A recitation of “a”, “an” or “the” is intended to mean “one or more” unless specifically indicated to the contrary.

All patents, patent applications, publications, and descriptions mentioned above are herein incorporated by reference in their entirety for all purposes. None is admitted to be prior art.

What is claimed is:

1. A modular housing adapted to house a data center, the modular housing comprising:
a) a plurality of panels;
b) at least one modular cooling pallet;
c) a plurality of wall structures; and
d) at least one cooling module on the at least one modular cooling pallet, wherein the plurality of panels and the plurality of wall structures form an enclosure housing the data center, the at least one modular cooling pallet, and the at least one cooling module.

2. The modular housing of claim 1, wherein the at least one modular cooling pallet with the at least one cooling module is at the top of the enclosure.

3. The modular housing of claim 2, wherein the at least one modular cooling pallet forms a peak.

4. The modular housing of claim 3, wherein the enclosure is configured to enclose a first row of computers and second row of computers, wherein the at least one cooling module directs cooled air downwards between the first and second rows of computers.

5. The modular housing of claim 4, wherein each of the at least one modular cooling pallet comprises a modular cooling pallet frame to which one or more of the at least one cooling module is attached.

6. The modular housing of claim 5 further comprising:
a plurality of fluid supply lines configured to pass passing cooling fluid into each of the at least one cooling module.

7. The modular housing of claim 6 further comprising:
a plurality of fluid return lines configured to remove cooling fluid from each of the at least one cooling module.

8. The modular housing of claim 7, wherein each of the at least one cooling module comprises a fan, a heat exchanger coil, and a duct.

9. The modular housing of claim 8, wherein the heat exchanger coil is configured to receive the cooling fluid from a fluid supply line, wherein the cooling fluid in the heat exchanger coil removes heat from the air drawn into the duct by the fan.

10. The modular housing of claim 9, wherein the heat exchanger coil is configured to remove the heated cooling fluid from the cooling module through a fluid return line.

11. The modular housing of claim 1 wherein the at least one cooling module comprises a first cooling module and a second cooling module, the first and second cooling modules each configured to provide different cooling properties.

12. The modular housing of claim 11, wherein the first cooling module is configured to cool air to a cooler temperature than that of the air cooled by the second cooling module.

13. The modular housing of claim 1, wherein the at least one cooling module comprises a first cooling module and a second cooling module, the first and second cooling modules each configured to be different sizes.

14. The modular housing of claim 1, wherein the at least one cooling pallet comprises an unpopulated area on which no cooling module is attached.

15. The modular housing of claim 1 further comprising:
a rack pallet at the bottom of the modular housing for supporting the plurality of wall structures, the rack pallet configured to receive a plurality of wires; and
the plurality of wires in the rack pallet, the plurality of wires being electrically coupled to the first and second rows of computers.

16. A method comprising:
assembling the modular housing of claim 1.

17. A modular housing system adapted to house a data center, the modular housing system comprising:
a modular housing comprising:
a) a plurality of panels,
b) at least one modular cooling pallet,
c) a plurality of wall structures, and
d) at least one cooling module on the at least one modular cooling pallet, wherein the plurality of panels and the plurality of wall structures form an enclosure housing the data center, the at least one modular cooling pallet, and the at least one cooling module;
a first row of computers; and
a second row of computers.

18. The system of claim 17, wherein the at least one modular cooling pallet with the at least one cooling module is at the top of the enclosure.

19. The system of claim 17, wherein the modular housing is configured to enclose the first row of computers and the second row of computers, wherein the at least one cooling module directs cold air downwards between the first and second rows of computers.

20. The system of claim 17 wherein the at least one cooling modules is configured to direct cold air downward between the first and second rows of computers, wherein the cold air passes through the first row of computers to form a first hot air stream that passes between the first row of computers and an adjacent first wall structure, and wherein the cold air passes through the second row of computers to form a second hot air stream that passes between the second row of computers and an adjacent second wall structure.

21. The system of claim 17, wherein the at least one cooling module is configured to draw hot air from the first hot air stream or the second hot air stream, cools the hot air, and redirects the cooled air downward between the first and second rows of computers.

22. The system of claim 17, wherein the at least one cooling module comprises a first cooling module and a second cooling module, the first and second cooling modules each configured to provide different cooling properties.

23. The system of claim 22, wherein the first cooling module cools air to a cooler temperature than that of the air cooled by the second cooling module.

24. The system of claim 17, wherein the at least one cooling module comprises a first cooling module and a second cooling module, the first and second cooling modules each configured to be different sizes.

25. The system of claim 17 further comprising:
a rack pallet at the bottom of the modular housing for supporting the plurality of wall structures, the rack pallet configured to receive a plurality of wires; and
the plurality of wires in the rack pallet, the plurality of wires being electrically coupled to the first and second rows of computers.

26. A method of using the system of claim 17, the method comprising:
receiving hot air from the first hot air stream or the second hot air stream;
cooling the hot air using the at least one cooling module, wherein each of the at least one cooling module cools the hot air to a certain temperature; and
directing the cooled air downwards between the first and second rows of computers.
